(19) United States
(12) Patent Application Publication
(10) Pub. No.: US 2026/0005105 A1
(43) Pub. Date: Jan. 1, 2026

(54) Communication Channels for a Stacked Die Configuration

(71) Applicant: Advanced Micro Devices, Inc., Santa Clara, CA (US)

(72) Inventors: Patrick James Shyvers, Fort Collins, CO (US); Matthew Donald Schoenwald, Fort Collins, CO (US); William Louie Walker, Fort Collins, CO (US)

(73) Assignee: Advanced Micro Devices, Inc., Santa Clara, CA (US)

(21) Appl. No.: 18/757,696

(22) Filed: Jun. 28, 2024

(51) Int. Cl. H01L 23/48; H01L 25/065

(52) U.S. Cl. CPC H01L 23/48; H01L 25/0657

(57) ABSTRACT

Temporary system adjustment for communication channels for a stacked die configuration is described. In accordance with the described techniques, a system includes a first die that has one or more communication channels for transporting data to a destination across the first die, a switch configured to communicably couple to a second die stacked on the first die, and steering logic configured to route the data to the destination via the switch and over one or more communication channels of the second die. If the second die is detected, the steering logic is configured to route data to the destination over the communication channels of the second die and/or over the communication channels of the first die. If the second die is not detected, the steering logic is configured to route data to the destination over the communication channels of the first die.

### BACKGROUND

A semiconductor wafer is a slice of semiconductor material, such as silicon, on which multiple integrated circuits or chips are fabricated. The semiconductor wafer is split into individual semiconductor components, referred to as dies. In one or more variations, a die includes one or more execution units, control units, registers, cache memories, and other functional units that enable execution of instructions. Further, the die includes one or more physical communication channels, or interconnects, which facilitate communication between different components of the die.

On-chip networks are used to facilitate the transportation of data via the physical communication channels to the different components of the die. An on-chip network includes communication infrastructure integrated onto the die, such as one or more buses, point-to-point connections, or more complex mesh architectures. On-chip networks can also be referred to as a network-on-chip, an interconnect fabric, or a data fabric.

### BRIEF DESCRIPTION OF THE DRAWINGS

FIG. 1 is a block diagram of a non-limiting example system having one or more dies operable to implement communication channels for a stacked die configuration.

FIGS. 2A and 2B are non-limiting examples of a top view and a side view of a stacked die configuration.

FIG. 3 depicts a non-limiting example system having a stacked die and a base die operable to implement communication channels for a stacked die configuration.

FIG. 4 depicts a non-limiting example system having a base die operable to implement communication channels for a stacked die configuration.

FIG. 5 depicts a procedure in an example implementation of communication channels for a stacked die configuration.

FIG. 6 depicts a procedure in an example implementation of communication channels for a stacked die configuration.

FIG. 7 is a block diagram of a processing system configured to execute one or more applications, in accordance with one or more implementations.

### DETAILED DESCRIPTION

### Overview

Conventionally, a manufacturer of a die selects a bandwidth or a latency tradeoff when designing an on-chip network for the die. To reduce a latency for routing the data, where the latency includes an amount of time it takes for data to travel from one point to another within the on-chip network, a design of the on-chip network may be simplified by reducing a number of intermediate nodes or switches and minimizing a distance data travels within the on-chip network. However, reducing latency comes at the expense of bandwidth due to reducing a number of concurrent data transfers that occur. Similarly, to increase an amount of data transferred during a time interval, referred to as a transmission bandwidth or bandwidth, the on-chip network may be constructed to include wider data paths, include additional data routing mechanisms, or utilize parallel data transfers simultaneously. Increasing bandwidth can result in increased latency due to the additional processing overhead for the additional data transfers.

To maximize a transmission bandwidth, a manufacturer of a die can allocate additional space on the die to physical communication channels. However, an amount of physical space on the die is finite, so allocating additional space to physical communication channels can result in reduced functionality of the die due to leaving less space for other components of the die (e.g., processor and/or memory components). Additionally, or alternatively, failing to increase the resource allocation to the physical communication channels can result in reduced functionality of the die due to insufficient bandwidth for data transmissions via the physical communication channels. In conventional techniques, as the size of transistors decrease, the physical communication channels for the data to move across the die are not scaled to match. Thus, a number and/or size of the physical communication channels is insufficient relative to a volume of data being shuttled around the die, which reduces the bandwidth of the on-chip network. Even if the size of the physical communication channels is increased to improve the bandwidth, the additional throughput resulting from the increased size of the physical communication channels increases latency, causing delays and performance degradation.

Additionally or alternatively, conventional designs for an on-chip network include routing data through an outer shell of a die, referred to as a package, or include changing the package architecture to bring data closer in the package to a target destination at the die. However, material characteristics of the packages are inferior to material characteristics of a die (e.g., silicon) regarding route density and performance related to transferring data through the material. Thus, the improvements to bandwidth when routing data through a package to a target destination at a die are minor, and delays or performance degradation are still experienced.

As described herein, an on-chip network includes additional physical communication channels, hereafter referred to as communication channels, to optionally route data via a stacked die in a 3-dimensional (3D) die architecture. In a 3D die architecture, one or more dies are stacked on a base die. The dies stacked on the base die are referred to as stacked dies and contrast with dies arranged in a side-by-side manner. The on-chip network optionally utilizes additional communication channels between the base die and the stacked die to route data transmissions from an initial destination on the base die through communication channels at the stacked die and back to a target destination at the base die. The on-chip network utilizes the additional communication channels and/or communication channels at the base die to route the data transmission from the initial destination to the target destination depending on one or more of the presence or absence of the stacked die, a latency sensitivity of the data, or a bandwidth criteria of the data. In variations, the latency sensitivity corresponds to one or more threshold latencies for the data, while the bandwidth criteria correspond to one or more threshold bandwidths for the data.

Further, the on-chip network utilizes steering logic to drive data transmissions (e.g., packets) on and off the base die via the additional communication channels by detecting whether a stacked die is present, evaluating a latency sensitivity of the data, and/or evaluating a bandwidth criteria of the data. That is, if there is a stacked die coupled to the base die, the steering logic indicates for the on-chip network to steer data via the additional communication channels according to one or more threshold bandwidths and/or one or more threshold latencies for the data. If the die is not stacked, the steering logic indicates for the on-chip network to steer data via communication channels at the base die and does not use the additional communication channels. In addition to the steering logic, or as an alternative, the design includes a configuration, a fuse, a pad, or any other feature that provides information indicating a presence or an absence of the stacked die and corresponding communication channels. The additional communication channels provide scalability for increasing an amount of data routed over the dies during an interval of time to a degree previously unavailable (e.g., double, or triple bandwidth for the die). Further, the additional communication channels provide reduced latency by providing additional pathways or routes for data transmissions. The improved bandwidth and reduced latency improve performance of a base die by increasing signaling throughput for the base die and reducing communication delays.

In some aspects, the techniques described herein relate to a system including a first die having one or more communication channels for routing data to a destination across the first die, a switch configured to communicably couple to a second die stacked on the first die, and steering logic configured to route the data to the destination via the switch and over one or more communication channels of the second die based on detection of the second die.

In some aspects, the techniques described herein relate to a system, where the system further includes the second die, and where the steering logic is further configured to detect presence of the second die.

In some aspects, the techniques described herein relate to a system, where the steering logic is further configured to route the data to the destination over the one or more communication channels of the second die and bypass the one or more communication channels of the first die based on detecting the presence of the second die.

In some aspects, the techniques described herein relate to a system, where the steering logic is further configured to both route the data over the one or more communication channels of the second die to the destination and route additional data over the one or more communication channels of the first die to the destination.

In some aspects, the techniques described herein relate to a system, where the steering logic is further configured to route the data over the one or more communication channels of the second die to the destination based on at least one of a threshold latency for routing the data, a threshold latency for routing the additional data, a threshold bandwidth of the one or more communication channels of the first die, or a threshold bandwidth of the one or more communication channels of the second die.

In some aspects, the techniques described herein relate to a system, where the steering logic is further configured to route the data over the one or more communication channels of the second die to the destination based on at least one of minimizing a latency of routing the data over the one or more communication channels of the second die, minimizing a latency of routing the additional data over the one or more communication channels of the first die, maximizing an amount of data routed over the one or more communication channels of the second die during an interval of time, or maximizing an amount of data routed over the one or more communication channels of the second die during the interval of time.

In some aspects, the techniques described herein relate to a system, where a transmission time period associated with the additional data is greater than a transmission time period associated with the data.

In some aspects, the techniques described herein relate to a system, where the steering logic is configured to maximize an amount of data routed over the one or more communication channels of the second die and the one or more communication channels of the first die based on routing the data over the one or more communication channels of the second die and routing the additional data over the one or more communication channels of the first die.

In some aspects, the techniques described herein relate to a system, where the steering logic is configured to minimize one or more of a transmission time period associated with the data or a transmission time period associated with the additional data based on routing the data over the one or more communication channels of the second die and routing the additional data over the one or more communication channels of the first die.

In some aspects, the techniques described herein relate to a system, where the system further includes the second die stacked on the first die, and where to route the data to the destination, the steering logic is further configured to route the data to the destination over the one or more communication channels of the first die to the destination based on one or more of a transmission time period associated with the data or a threshold corresponding to an amount of data routed over the one or more communication channels of the first die.

In some aspects, the techniques described herein relate to a system, where to route the data to the destination, the steering logic is further configured to route the data over the one or more communication channels of the first die to the destination based on failing to detect the second die.

In some aspects, the techniques described herein relate to a system, where, to detect the second die, the steering logic is further configured to receive a signal associated with one or more of a fuse, configuration information, or a pad, where the signal indicates the second die is stacked on the first die.

In some aspects, the techniques described herein relate to a method including detecting a second die stacked on a first die, the first die having one or more communication channels for routing data to a destination across the first die, and routing, via a switch on the first die configured to communicably couple to the second die, the data to the destination over one or more communication channels of the second die based on detection of the second die.

In some aspects, the techniques described herein relate to a method, where routing the data to the destination further includes bypassing the one or more communication channels of the first die based on the detection of the second die.

In some aspects, the techniques described herein relate to a method, further including routing both the data over the one or more communication channels of the second die to the destination and routing additional data over the one or more communication channels of the first die to the destination based on the detection of the second die.

In some aspects, the techniques described herein relate to a method, where routing the data over the one or more communication channels of the second die to the destination is based on at least one of a threshold latency for routing the data, a threshold latency for routing the additional data, a threshold bandwidth of the one or more communication channels of the first die, or a threshold bandwidth of the one or more communication channels of the second die.

In some aspects, the techniques described herein relate to a method, where routing the data over the one or more communication channels of the second die to the destination is based on at least one of minimizing a latency of routing the data over the one or more communication channels of the second die, minimizing a latency of routing the additional data over the one or more communication channels of the first die, maximizing an amount of data routed over the one or more communication channels of the second die during an interval of time, or maximizing an amount of data routed over the one or more communication channels of the second die during the interval of time.

In some aspects, the techniques described herein relate to a method, where detecting the second die further includes receiving a signal associated with one or more of a fuse, configuration information, or a pad, the signal indicating the second die is stacked on the first die.

In some aspects, the techniques described herein relate to a method including detecting an absence of a second die stacked on a first die, the first die having one or more communication channels for routing data to a destination across the first die, and routing, via a switch on the first die configured to communicably couple to the second die, the data to the destination across the first die over the one or more communication channels of the first die based on detecting the absence of the second die.

In some aspects, the techniques described herein relate to a method, where detecting the absence of the second die further is based on a signal associated with one or more of a fuse, configuration information, or a pad, the signal indicating the second die is not stacked on the first die.

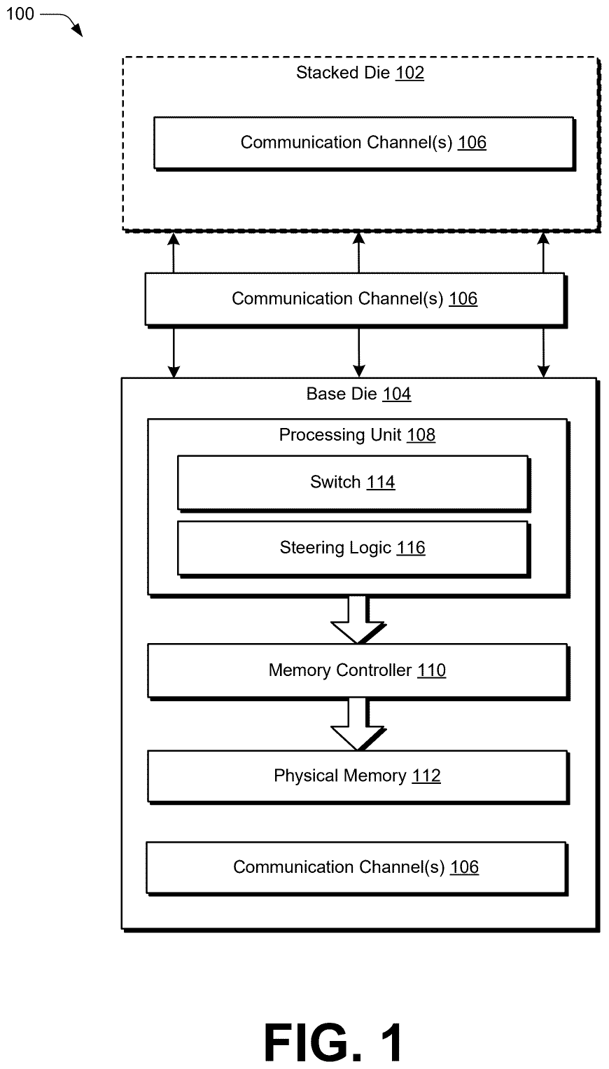

FIG. 1 is a block diagram of a non-limiting example system having one or more dies operable to implement communication channels for a stacked die configuration. In this example, the system 100 includes a stacked die 102 and a base die 104, as well as one or more communication channels 106. The stacked die 102 and/or the base die 104 include one or more functional units, including a processing unit 108, a memory controller 110, and physical memory 112 (e.g., volatile or nonvolatile memory) that are communicatively coupled, one to another. The stacked die 102 and/or the base die 104 are configurable to be implemented by a device in a variety of ways. Examples of which include, by way of example and not limitation, computing devices, servers, mobile devices (e.g., wearables, mobile phones, tablets, laptops), processors (e.g., graphics processing units, central processing units, and accelerators), digital signal processors, disk array controllers, hard disk drive host adapters, memory cards, solid-state drives, wireless communications hardware connections, Ethernet hardware connections, switches, bridges, network interface controllers, and other apparatus configurations. It is to be appreciated that in various implementations, the device is configured as any one or more of those devices listed just above and/or a variety of other devices without departing from the spirit or scope of the described techniques.

In the illustrated example, the processing unit 108 executes software (e.g., an operating system, applications, etc.) to issue a memory request to the memory controller 110. The memory request is configurable to cause storage (e.g., programming) of data to physical memory as a write request or read data from the physical memory 112 as a read request. The memory controller 110 is configured to manage use of memory cells in the physical memory 112. Memory cells are configured in hardware of the physical memory 112 as electronic circuits that are used to store data. In one or more implementations, the data includes sequences of bits that represent information, including, but not limited to, instructions for executing tasks or operations between different functional units of the stacked die 102 and/or the base die 104, addresses for the memory cells, audio data representing audio samples, image data representing image frames, video data representing vide frames, control signaling that manages settings, configurations, and operation of the functional units, and/or raw sensor readings representing physical measurements transferred between one or more sensors and the processing unit 108, among other examples of data. It is to be appreciated also, that in at least one variation, the system 100 does not include one or more of the depicted components and/or includes different components without departing from the spirit or scope of the described techniques.

In one or more implementations, during a manufacturing process of a processor and/or memory, a semiconductor material is split into individual semiconductor components, referred to as dies (e.g., the stacked die 102 and/or the base die 104). In variations, the stacked die 102 and/or the base die 104 are configured to implement aspects of a memory and/or a processor. By way of example, the stacked die 102 and/or the base die 104 include circuitry configured to store and access data and/or execute instructions. The circuitry includes one or more transistors and/or switches 114 arranged to implement functionality of a processor and/or memory. The circuitry is arranged and also applied using logic (e.g., steering logic 116) that enables the stacked die 102 and/or the base die 104 to carry out the functionalities described above and below.

The stacked die 102 and/or the base die 104 include one or more execution units, control units, registers, cache memories, and other functional units that enable execution of instructions. Execution units are functional components within a processor that perform types of operations, including arithmetic operations, logic operations, and/or operations related to data movement. Example execution units include, but are not limited to, an arithmetic logic unit (ALU) for performing basic arithmetic, a floating-point unit (FPU) for performing floating-point arithmetic operations, a load-store unit for loading data from memory into registers and storing data from registers back to memory, and a memory management unit to translate virtual addresses to physical addresses for memory access and management, to name just a few. A control unit (e.g., the processing unit 108, the memory controller 110, and/or a unit communicatively coupled with the memory controller 110 or the processing unit 108) manages the execution of instructions, directs flow of data, and coordinates operations within the stacked die 102 and/or the base die 104. For example, a control unit manages execution of instructions retrieved from memory, including decoding the instructions and controlling the flow of data in response to the instructions between different components of the stacked die 102 and/or the base die 104.

In one or more implementations, the physical memory 112 includes one or more registers and/or one or more cache memories. The memory controller 110 of the stacked die 102 and/or the base die 104 utilizes registers to store and access data that is actively being processed or manipulated. Additionally, or alternatively, the stacked die 102 and/or the base die 104 utilize one or more cache memories (e.g., multiple level cache memory) to store and access frequently utilized data.

The stacked die 102 and/or the base die 104 are manufactured from a substrate layer (e.g., made from silicon) and include electronic circuits that performs various operations on and/or using data in the physical memory 112. Examples of the stacked die 102 include, but are not limited to, a central processing unit (CPU), a graphics processing unit (GPU), a field programmable gate array (FPGA), an accelerator, an accelerated processing unit (APU), and a digital signal processor (DSP), to name a few. The processing unit 108, also referred to as a core, reads and executes instructions (e.g., of a program), examples of which include to add, to move data, and to branch. In variations, the processing unit 108 includes, or is configured to implement, one or more switches 114 for routing or moving data. Although one processing unit 108 is depicted in the illustrated example, in variations, the stacked die 102 and/or the base die 104 include more than one processing unit 108 (e.g., a multi-core processor).

A switch 114 is configured in hardware of the processing unit 108 as electronic circuits that are used to route data. A switch receives an incoming data packet, determines a source destination address for the data packet, and forwards the data packet to the source destination address by selecting one or more communication channels 106 over which to send the data packet. In one or more implementations, switches 114 of a base die 104 are configured to communicably couple to a stacked die 102. Although one switch 114 is depicted in the illustrated example, in variations, the stacked die 102 and/or the base die 104 include more than one switch 114.

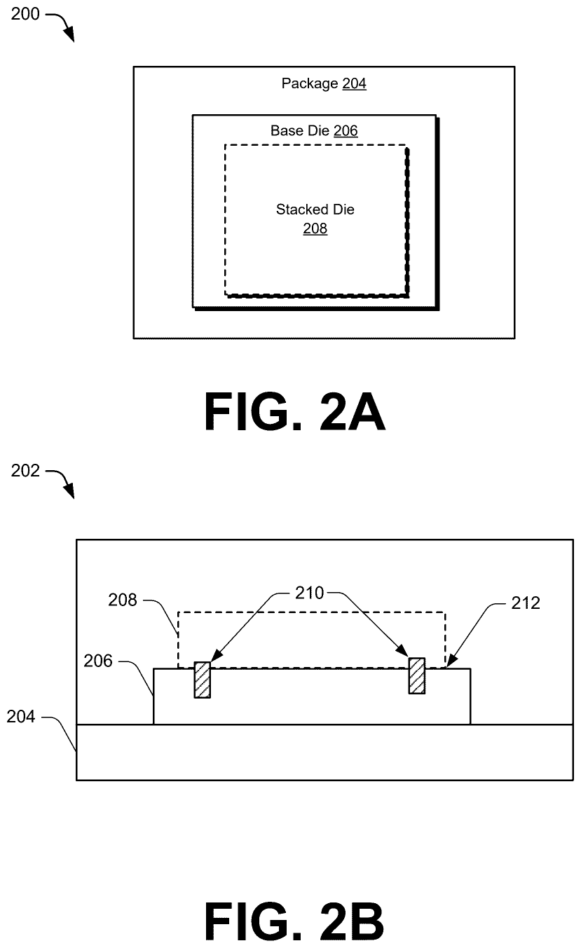

In one or more implementations, the stacked die 102 and the base die 104 are manufactured in a 3D architecture, such that one or more processor components and/or memory components (e.g., the stacked die 102) are bonded to a base die 104. The bonded components and the base die 104 make up a chip. In variations, the stacked die 102 and the base die 104 are manufactured independently and subsequently assembled via bonding techniques as layers in a stack of processor and/or memory components, which is described in further detail with respect to FIGS. 2A and 2B. Vertical interconnects, referred to as through-silicon vias (TSVs), are introduced in the stacked die 102 and/or the base die 104 to provide communication between the different layers or dies in the stack. It is to be appreciated that the base die 104 has any numerical quantity of stacked dies 102. In some other examples, the base die 104 is manufactured in a 2D architecture, such that the base die 104 does not have a stacked die 102. That is, the base die 104 is optionally coupled with the stacked die 102.

The dies representing the different layers of a stack for a 3D architecture and/or a die in a 2D architecture are configured to implement functionality of a processor and/or a memory by utilizing communication channels 106. The communication channels 106 are components of the system 100 that facility movement of data between components of a die for the 2D architecture or components of multiple dies in a stack for the 3D architecture. For example, the communication channels 106 provide for routing data between the processing unit 108, the memory controller 110/, and/or the physical memory 112, in addition, or as an alternative, to other components of the stacked die 102 and the base die 104. Example communication channels 106 include, but are not limited to, TSVs when moving data between layers and/or memory channels, buses (e.g., a data bus), interconnects, traces, or planes within a die to move data to different destinations or components of the die. The stacked die 102 and/or the base die 104 include communication channels 106 disposed within the stacked die 102 and the base die 104, respectively. In variations, the base die 104 includes additional communication channels 106 disposed within the base die 104 and directed towards the stacked die 102.

In variations, the communication channels 106 are part of an on-chip network. The on-chip network is also referred to as a network-on-chip, an interconnect fabric, or a data fabric. An on-chip network includes one or more switches 114 to enable routing of data packets between components, communication channels 106, buffers for temporarily storing data packets, and routing logic or steering logic 116 to determine a path for data packets to take from an initial destination to a target destination, among other features. In one or more examples, the steering logic 116 includes or is implemented in computer software and/or computer hardware, such as using logic gates, in processor architecture, and/or a computer program.

On-chip networks are used to shuttle data via the communication channels 106, or wires, to different components and/or destinations on compute areas of a die. For example, data is brought in from off-chip (e.g., from network or memory) to a corner, edge, or middle of the die, and the data is distributed across the compute area of the die by an interface of the on-chip network using the steering logic 116. The on-chip network is configured to distribute the data according to a high bandwidth with a low latency. In variations, a high bandwidth (e.g., a threshold bandwidth) is defined by a threshold value for an amount of data routed over communication channels during an interval of time (e.g., time period or duration). A low latency (e.g., a threshold latency) is defined by a transmission time period for the data. A transmission time period for the data is an elapsed time period over which the data is transmitted from an initial destination to a final destination. As transistor size has scaled down, the wires that create the physical channels for the data to move across the die have not scaled to match. Thus, in variations, there is an insufficient numerical quantity of wires relative to a volume of data being shuttled around the die, which reduces the bandwidth of the on-chip network. To improve the bandwidth, the size of the wires is reduced. However, smaller wires have inferior latency relative to larger wires, causing delays and performance degradation.

Conventional techniques involve a manufacturer of a die selecting a bandwidth or latency tradeoff when designing the on-chip network for the die. Designing a die with a tradeoff between bandwidth or latency results in reduced functionality of the die due to increased resource (e.g., metal) allocation to communication channels 106 and/or reduced functionality of the die due to insufficient bandwidth from reduced resource allocation to communication channels 106. Additionally, or alternatively, a manufacturer designs the on-chip network to perform routing in a package itself or changes a package architecture to bring data closer in the package to a destination. However, packages do not have the route density or performance of silicon, so the improvements to the bandwidth are minor, and delays or performance degradation are still experienced.

To improve bandwidth and/or latency without the tradeoff, an on-chip network is expanded to optionally include communication channels 106 of stacked dies. The on-chip network includes communication channels 106 disposed within a base die 104 and/or a stacked die 102 for transporting data to a destination across the base die 104 and the stacked die 102, respectively. Additionally, or alternatively, the base die 104 and/or the stacked die 102 include communication channels 106 disposed within the base die 104 and/or the stacked die 102 directed towards a coupling location between the stacked die 102 and the base die 104. The coupling location is a point where the stacked die 102 couples to the base die 104. The on-chip network optionally utilizes the communication channels 106 directed towards the coupling location between the stacked die 102 and the base die 104 depending on the presence or absence of the stacked die 102. Although the communication channels between the stacked die 102 and the base die 104 are depicted as being separate from the stacked die 102 and the base die 104, in one or more implementations, the communication channels 106 are disposed within the stacked die 102 and/or the base die 104.

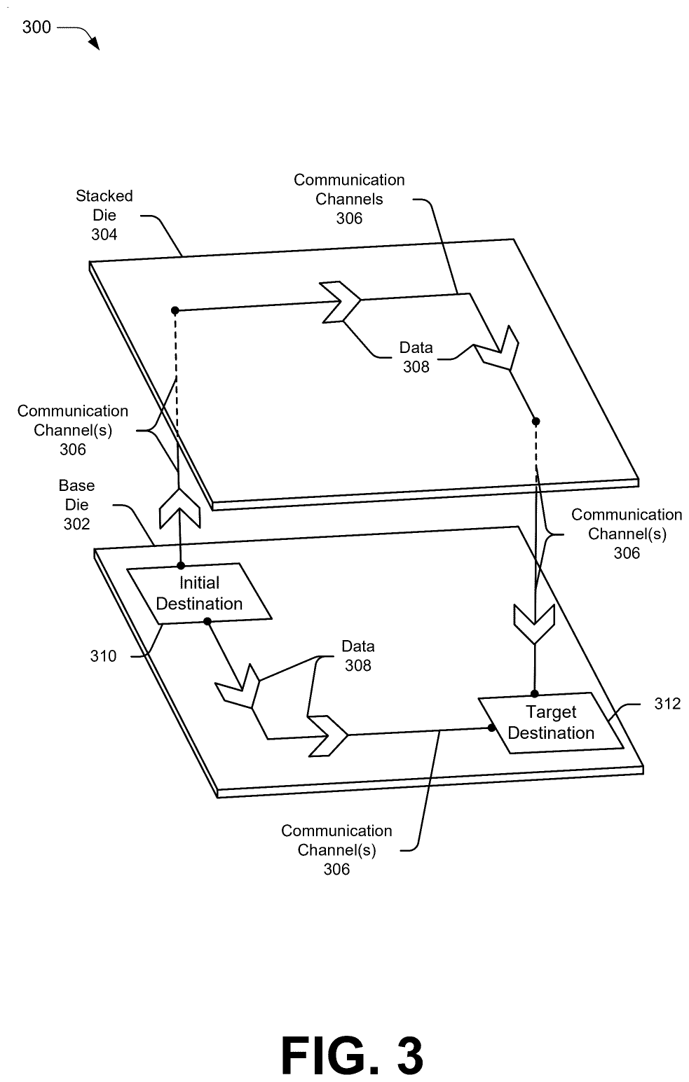

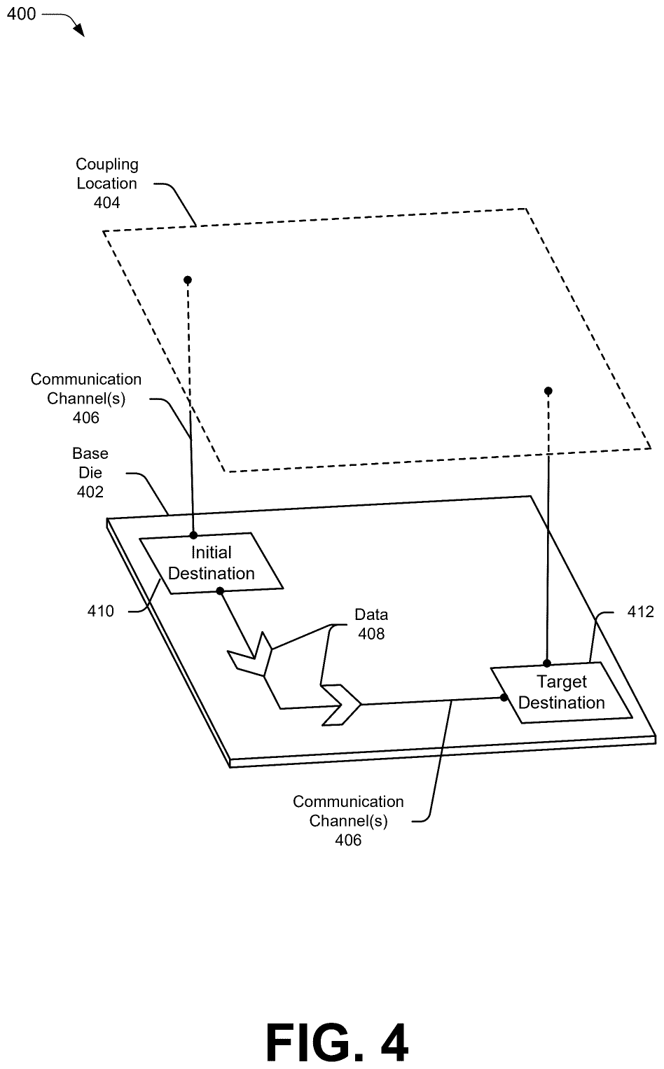

In one or more variations, if the stacked die 102 is present and coupled with the base die 104 (e.g., detected by the base die 104), then the on-chip network utilizes additional communication channels 106 to route transmissions from an initial destination at the base die 104 through communication channels 106 of the stacked die 102 to a target destination at the base die 104, which is described in further detail with respect to FIG. 3. Additionally, or alternatively, if the stacked die 102 is present and coupled with the base die 104, then the on-chip network utilizes latency and bandwidth criteria for data packets to route the data packets to target destinations through the stacked die 102 via the communication channels 106 of the stacked die or through the base die 104 without utilizing the communication channels 106 of the stacked die 102. That is, the on-chip network optionally bypasses the communication channels 106 of the base die 104. In some other examples, if the stacked die 102 is absent (e.g., not detected by the base die 104), then the on-chip network utilizes existing communication channels 106 at the base die 104 and not the communication channels 106 of the stacked die 102 to route transmissions to a target destination at the base die 104, which is described in further detail with respect to FIG. 4.

The on-chip network includes steering logic 116 at an interface (e.g., a network interface) that drives data packets on and off the base die 104. The interface implements the steering logic 116 to determine whether the communication channels 106 are present and routes data accordingly. That is, if the steering logic 116 detects the presence of the stacked die 102 on the base die 104, then the interface steers data from the base die 104 over communication channels 106 of the stacked die 102 to a target destination at the base die 104. If the steering logic 116 fails to detect the presence of the stacked die 102 on the base die 104, then the interface does not use the communication channels 106 of the base die 104 that are directed towards the stacked die 102 or the communication channels 106 of the stacked die 102. In addition to the steering logic 116, or as an alternative, the base die 104 includes configuration information, a fuse, a pad, or any other information that indicates the presence or absence of the stacked die 102 and corresponding communication channels 106, which is described in further detail with respect to FIGS. 2A and 2B.

Although the stacked die 102 is depicted and described as implementing aspects of a processor, in variations, the stacked die 102 implements aspects of memory in addition to, or as an alternative, to a processor.

In the context of utilizing additional communication channels for a stacked die configuration of the system 100, consider the following discussion of FIGS. 2A and 2B.

FIGS. 2A and 2B depict a non-limiting example top view 200 and a non-limiting example side view 202 of a stacked die configuration. The non-limiting example top view 200 and side view 202 include, or are implemented by, aspects of the system 100. For example, the non-limiting example top view 200 and side view 202 include a package 204 with a base die 206, a stacked die 208, and one or more communication channels 210, where the base die 206 is an example of a base die 104, the stacked die 208 is an example of a stacked die 102, and the communication channels 210 are examples of communication channels 106, as described with reference to FIG. 1.

The stacked die 208 is depicted above a portion of the base die 206, however, in one or more variations the stacked die 208 is below the base die 206. The base die 206 is depicted as adjacent to, or touching, the stacked die 208. In one or more implementations, additional layers are arranged between the base die 206 and the stacked die 208 (e.g., dielectric layers for electrically isolating individual layers).

In one or more implementations, one or more dies that make up an integrated circuit or chip are housed by a package 204. The package 204 provides mechanical support, electrical insulation, heat dissipation, and connection points for external circuitry, among other benefits, for the dies. In variations, the package 204 is manufactured from ceramic material, plastic material, and/or metal alloys. Although the package 204 is illustrated as surrounding the base die 206 and the stacked die 208, the package 204 is any shape or size.

As described with reference to FIG. 1, one or more dies that make up a chip are optionally stacked during a manufacturing process. For example, a base die 206 is configured to be coupled with one or more stacked dies 208. In variations, although the base die 206 is configured to be coupled with the stacked dies 208, the base die 206 is not coupled with the stacked dies 208. That is, the base die 206 makes up the chip (e.g., without additional dies). An example 3D die, or stacked die, configuration includes, but is not limited to, one or more dies stacked vertically on top of a base die 206. Coupling the stacked dies 208 to the base die 206 and/or to another stacked die 208 includes bonding the stacked dies 208 to the base die 206 and/or to the other stacked die 208.

In one or more variations, a base die 206 and/or a stacked die 208 detects the presence or absence of another die. For example, logic at the base die 206 detects the presence of one or more stacked die 208, while logic at the stacked die 208 detects the presence of the base die 206 and/or one or more additional stacked dies 208. In one or more implementations, the base die 206 and/or the stacked dies 208 include solder joints that contact a pad on an adjacent die to create an electrical connection. A pad is a dedicated area on the base die 206 and/or the stacked die 208 used for making electrical connections between the die and external components, used for testing during a manufacturing process, used for distributing power supply voltages and ground connections to inner circuitry of the die, and/or used for connecting input and output signals between the die and external components or systems. Example pads include, but are not limited to, metalized areas on the surface of a die or TSVs that pass through the die. The base die 206 and/or the stacked die 208 utilizes information regarding whether the electrical connection is established or not to detect the presence of the stacked die 208 (e.g., to detect whether the dies are in a 3D die configuration). In variations, the information includes a signal that indicates the connection is established.

In one or more other variations, the base die 206 and/or the stacked die 208 receives signaling that includes fuse information, configuration information, or any other information that indicates the presence or absence of a stacked die 208 coupled with the base die 206 and/or another stacked die 208 coupled with the stacked die 208. In variations, the base die 206 and/or the stacked die 208 includes a fuse, such as a thin layer of material that is bridged or connected the absence of a stacked die 208 but is broken or open when the stacked die 208 is present. The fuse information includes an indication of whether the fuse is connected or open, indicating the absence or presence of a stacked die 208, respectively. Additionally, or alternatively, the base die 206 receives configuration information that explicitly indicates the presence or absence of the stacked die 208 (e.g., from the stacked die 208). In one or more implementations, the configuration information includes one or more bits that indicate the presence or absence of the stacked die 208.

The base die 206 includes one or more communication channels 210 for routing data from an initial, or source, location on the base die 206 to a target destination on the base die 208, which is described in further detail with respect to FIGS. 3 and 4. Similarly, the stacked die 208 includes one or more communication channels 210 for routing data from an initial, or source, location on the stacked die 208 to a target destination on the stacked die 208, which is described in further detail with respect to FIG. 3. The base die 206 also includes one or more additional communication channels 210 for routing data towards a coupling location 212 between the base die 206 and an optional stacked die 208. Similarly, the stacked die 208 also includes one or more additional communication channels 210 for routing data towards a coupling location 212 between the base die 206 and the stacked die 208.

In some examples, such as if the stacked die 208 is present, the base die 206 selectively uses the additional communication channels 210 to route data from an initial location at the base die 206 through communication channels 210 of a stacked die 208 (e.g., if the stacked die 208 is present) and back to a target destination at the base die 206, which is described in further detail with respect to FIG. 3. In some other examples, such as if the stacked die 208 is not present, the base die 206 uses communication channels 210 at the base die 206 (e.g., without using the additional communication channels 210) to route data from an initial location at the base die 206 to a target destination at the base die 206, which is described in further detail with respect to FIG. 4.

FIG. 3 depicts a non-limiting example system 300 having a stacked die and a base die operable to implement communication channels for a stacked die configuration. The non-limiting example system 300 includes, or is implemented by, aspects of the system 100 and the non-limiting example top view 200 and side view 202. For example, the non-limiting example system 300 includes a base die 302, a stacked die 304, and one or more communication channels 306, which are examples of the corresponding features as described with reference to FIGS. 1 and 2.

Although the stacked die 304 is illustrated as being suspended over the base die 302, in variations, the stacked die 304 is at any orientation relative to the base die 302 (e.g., next to, above, below, etc.). In some examples, the stacked die 304 is coupled with the base die 302, as described with reference to FIGS. 2A and 2B.

In one or more examples, the communication channels 306 are embedded at the base die 302 and/or the stacked die 304. For example, the base die 302 includes communication channels 306 for routing data 308 from an initial destination 310 to a target destination 312 at the base die 302 (e.g., without utilizing the stacked die 304). Additionally, or alternatively, the stacked die 304 includes communication channels 306 for routing data 308 from the initial destination at the base die 302 to the target destination 312 at the base die 302 by bypassing the communication channels 306 of the base die 302. In variations, the initial destination 310 is a component of the base die 302 and the target destination 312 is another component of the base die 302. Example components include, but are not limited to, a processing unit 108, a memory controller 110, and a physical memory 112, as described with reference to FIG. 1. Similarly, the stacked die 304 includes communication channels 306 for routing data 308 between locations at the stacked die 304. The data 308 includes one or more of instructions for executing a command, information obtained from, or to be stored at, memory of the base die 302 and/or the stacked die 304, or any other signaling.

In some examples, the base die 302 includes additional communication channels 306 directed towards the stacked die 304 (e.g., when the stacked die 304 is present), or directed towards a coupling location of the stacked die 304 to the base die 302. Similarly, the stacked die 304 includes additional communication channels directed towards the base die 302. The base die 302 selectively utilizes the additional communication channels 306 to route the data 308 between the initial destination 310 at the base die 302 and the target destination 312 at the base die 302 over communication channels 306 of the stacked die 304.

The use of the additional communication channels 306 depends on implementation. For example, the base die 302 reduces latency in the system 300 by routing the data 308 via the additional communication channels 306. The additional communication channels 306 facilitate rapid transmission of the data 308 directly between various points on the base die 302, including between an initial destination 310 and a target destination 312, without routing the data through intermediate components that slow the transmission of the data 308 (e.g., like a superhighway). Thus, if the system 300 has a relatively low latency criteria (e.g., requirement), then logic at the base die 302 is configured to route the data 308 via the additional communication channels 306 to reduce a latency of transmission of the data 308.

In some other examples, the base die 302 reduces latency for transmission of one or more data packets, without reducing latency for transmission of other data packets. That is, the base die 302 evaluates a latency criteria for transmission of the data 308 to determine whether the data 308 is latency sensitive. Example data 308 that is latency sensitive includes, but is not limited to, data 308 with content to be used immediately or within a relatively short period of time. Example data 308 that is not latency sensitive includes, but is not limited to, data 308 with content that is not used within the relatively short period of time or data 308 that is part of an out-of-order window. In variations, the base die 302 routes data 308 that is latency sensitive utilizing different communication channels 306 than data 308 that is not latency sensitive.

For example, the base die 302 routes data 308 that is latency sensitive to a target destination 312 via the additional communication channels 306 through the stacked die 304. The base die 302 routes data 308 that is not latency sensitive to a target destination 312 (e.g., a same target destination 312 as the latency sensitive data 308 or a different target destination 312 than the latency sensitive data 308) utilizing one or more communication channels 306 at the base die 302, without routing the data through the stacked die 304. In some other examples, the base die 302 routes data 308 that is latency sensitive to a target destination 312 utilizing one or more communication channels 306 at the base die 302, without routing the data through the stacked die 304. The base die 302 routes data 308 that is not latency sensitive to a target destination 312 (e.g., a same target destination 312 as the latency sensitive data 308 or a different target destination 312 than the latency sensitive data 308) via the additional communication channels 306 through the stacked die 304.

In one or more implementations, the base die 302 monitors a latency and bandwidth of the system 300, and utilizes information collected from the monitoring to balance latency and bandwidth by routing the data 308 via the additional communication channels 306 thought the stacked die 304 and/or routing the data 308 via communication channels 306 at the base die 302 (e.g., without utilizing the stacked die 304). For example, the latency of the transmission of the data 308 is balanced with the bandwidth of the transmission of the data 308. In variations, balancing latency and bandwidth includes maximizing a bandwidth while minimizing a latency of data transfer in the system 300. That is, the data 308 transmission satisfies a threshold latency and/or a threshold bandwidth. In variations, the information includes one or more of a duration or period of time for the data 308 to arrive at the target destination 312 from the initial destination 310, a volume or quantity of data 308 transmitted between the initial destination 310 and the target destination 312 for a duration, or any other information related to latency or bandwidth of data 308 at the system 300.

In some examples, the base die 302 utilizes the additional communication channels 306 to maximize a bandwidth of the system 300. If the system 300 is implemented in a high bandwidth use case, such as for bulk data processing, video processing and rendering, machine learning training, among other use cases, the on chip-network of the base die 302 determines to prioritize bandwidth over latency to keep the communication channels 306 at the base die 302 uncongested. To maximize bandwidth of the system 300, the base die 302 routes a quantity of data 308 to one or more target destinations 312 at the base die 302 over one or more communication channels 306 of the base die 302 and one or more communication channels 306 of the stacked die 304 to the extent that the communication channels 306 are capable of transferring the data 308.

In variations, the base die 302 utilizes steering logic in an on-chip network to make the determination of whether to route data 308 to one or more target destinations 312 through communication channels 306 at the stacked die 304 or through communication channels at the base die 302 (e.g., without utilizing the communication channels 306 at the stacked die 304). For example, the steering logic evaluates latency criteria of transmission of the data 308, bandwidth criteria of transmission of the data 308, latency criteria of the system 300, and/or bandwidth criteria of the system 300 to route the data 308 over the communication channels 306 of the stacked die 304 and/or over the communication channels 306 of the base die 302. The bandwidth criteria include, but are not limited to, a volume of data transmitted over the communication channels 306 over a period of time. The latency criteria include, but are not limited to, a time it takes for the data to be transmitted from an initial destination to a target destination.

FIG. 4 depicts a non-limiting example system 400 having a base die operable to implement communication channels for a stacked die configuration. The non-limiting example system 400 includes, or is implemented by, aspects of the system 100 and the non-limiting example top view 200 and side view 202. For example, the non-limiting example system 400 includes a base die 402 and one or more communication channels 406, which are examples of the corresponding features as described with reference to FIGS. 1 and 2.

In variations, the base die 402 is not coupled with a stacked die at a coupling location 404. The coupling location 404 is a location at the base die 402 where a stacked die, if present, would couple with the base die 402. Although the coupling location 404 is illustrated as being vertically adjacent to the base die 402, in variations, the coupling location 404 is at any orientation relative to the base die 402 (e.g., next to, above, below, etc.).

In one or more examples, the communication channels 406 are embedded at, or disposed within, the base die 402. For example, the base die 402 includes communication channels 406 for routing data 408 from an initial destination 410 to a target destination 412 at the base die 402 (e.g., without utilizing a stacked die). In variations, the initial destination 410 is a component of the base die 402 and the target destination 412 is another component of the base die 402. Example components include, but are not limited to, the processing unit 108, the memory controller 110, and the physical memory 112, as described with reference to FIG. 1. The data 408 includes one or more of instructions for executing a command, information obtained from, or to be stored at, memory of the base die 402, or any other signaling.

The base die 402 includes additional communication channels 406 directed towards the coupling location 404 (e.g., when the stacked die is absent). In variations, the base die 402 detects the presence or absence of the stacked die at the coupling location 404, as described with reference to FIGS. 2A and 2B. If the stacked die is present, then the base die 402 optionally routes data 408 to the target destination 412 via the stacked die, as described with reference to FIG. 3. If the base die 402 fails to detect a stacked die and/or detects an absence of a stacked die, then the base die 402 routes the data 408 via the communication channels 406 at the base die 402 (e.g., without utilizing a stacked die). For example, steering logic of an on-chip network at the base die 402 determines the stacked die is absent and routes the data 408 from the initial destination 410 to the target destination 412 at the base die 402 via communication channels 306 at the base die 402.

Having discussed example systems and non-limiting examples of utilizing communication channels for a stacked die configuration, consider the following example procedures.

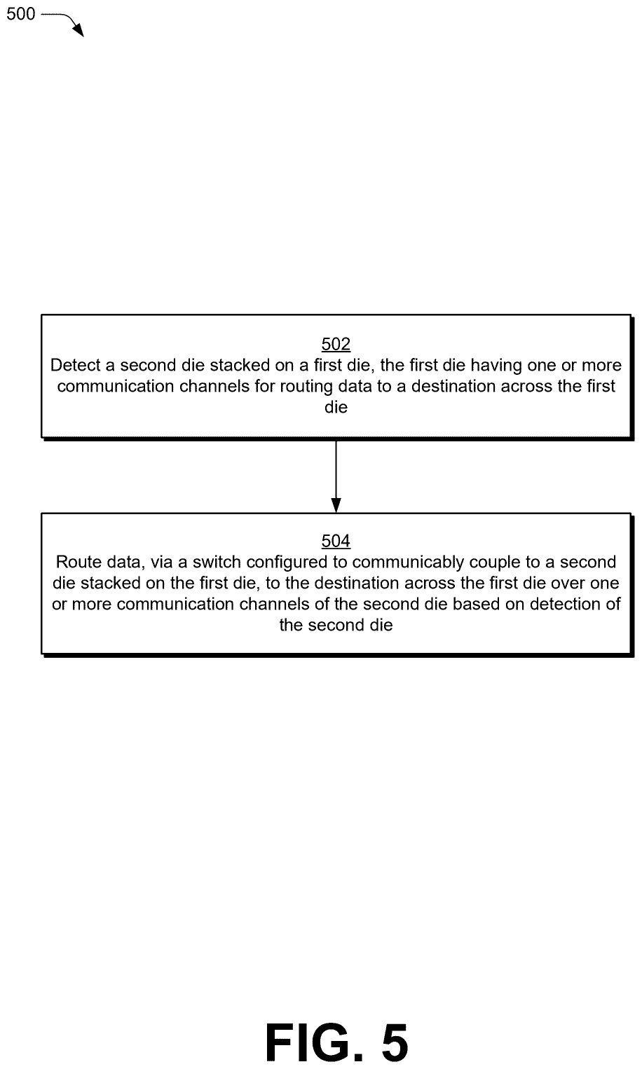

FIG. 5 depicts a procedure 500 in an example implementation of communication channels for a stacked die configuration.

At 502, a second die is detected. The second die is stacked on a first die, where the second die is referred to as the stacked die and the first die is referred to as a base die. The base die has one or more communication channels for routing data to a destination across the base die. The communication channels are disposed within the base die.

In some examples, the stacked die is detected by receiving a signal indicating the presence of the stacked die. Example information in the signal includes, but is not limited to, one or more of a fuse signal, configuration information, or a pad signal.

At 504, data is routed to the destination across the first die via a switch configured to communicably couple to the stacked die. In variations, the data is routed to the destination over one or more communication channels of the stacked die if the stacked die is detected (e.g., present). For example, the base die and/or the stacked die include one or more additional communication channels directed towards a coupling location between the stacked die and the base die. The base die routes the data to the destination at the base die via the stacked die using the additional communication channels and communication channels of the stacked die.

In some examples, routing the data to the destination includes bypassing communication channels of the base die if the stacked die is detected. In one or more other examples, routing the data includes routing data via the communication channels of the stacked die and/or the communication channels of the base die to one or more destinations at the base die.

In variations, the routing of the data via the communication channels of the stacked die and/or the communication channels of the base die is based on a latency criteria of transmission of the data and/or a bandwidth criteria of the data. For example, steering logic at the base die is configured to balance the latency and bandwidth of the data to maximize the bandwidth, while minimizing the latency. In some other examples, the steering logic at the base die is configured to minimize latency for latency sensitive data, and not minimize latency for data that is not latency sensitive (e.g., based on a latency criteria of transmission of the data). Data that is not latency sensitive is transmitted with a greater latency (e.g., transmission time period) than data that is latency sensitive. In yet other examples, the steering logic at the base die is configured to maximize a bandwidth criteria for transmission of the data. In yet other examples, the steering logic at the base die is configured to minimize a latency of transmission of the data. Thus, the data is routed over the communication channels of the second die based on a threshold latency for routing the data, a threshold latency for routing the additional data, a threshold bandwidth of the one or more communication channels of the first die, and/or a threshold bandwidth of the one or more communication channels of the second die. Additionally, or alternatively, the data is routed over the communication channels of the second die based on minimizing a latency of routing the data over the one or more communication channels of the second die, minimizing a latency of routing the additional data over the one or more communication channels of the first die, maximizing an amount of data routed over the one or more communication channels of the second die during an interval of time, and/or maximizing an amount of data routed over the one or more communication channels of the second die during the interval of time.

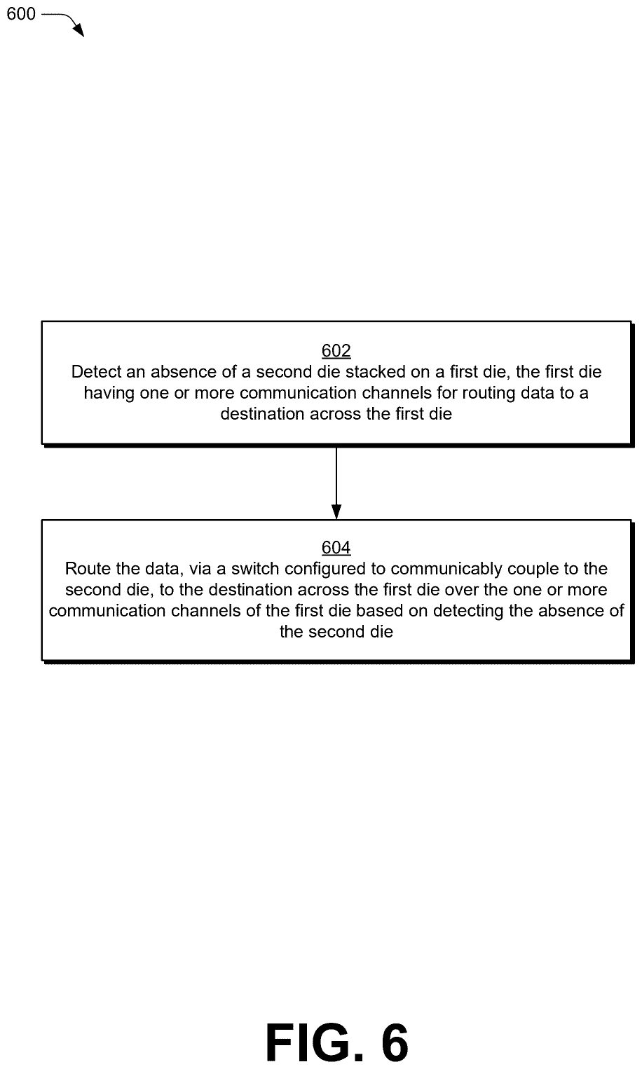

FIG. 6 depicts a procedure 600 in an example implementation of communication channels for a stacked die configuration.

At 602, an absence of a second die stacked on a first die is detected (e.g., the second die is failed to be detected). The first die includes a switch configured to communicably couple to the second die. The second die is referred to as the stacked die and the first die is referred to as a base die. The base die has one or more communication channels for transporting data to a destination across the base die. The communication channels are disposed within the base die.

In some examples, the absence of the stacked die is detected by receiving a signal indicating the absence of the stacked die. Example information in the signal includes, but is not limited to, one or more of a fuse signal, configuration information, or a pad signal.

At 604, data is routed to the destination across the first die via the switch configured to communicably couple to the stacked die. The data is routed to the destination over one or more communication channels of the first die based on detecting the absence of the second die.

In variations, the base die includes one or more additional communication channels directed towards a location where the stacked die would be coupled to the base die. The additional communication channels are for routing the data over the one or more communication channels of the stacked die.

It should be understood that many variations are possible based on the disclosure herein. Although features and elements are described above in particular combinations, each feature or element is usable alone without the other features and elements or in various combinations with or without other features and elements.

The various functional units illustrated in the figures and/or described herein (including, where appropriate, the stacked die 102, the base die 104, the communication channels 106, the switches 114, and the steering logic 116) are implemented in any of a variety of different manners such as hardware circuitry, software or firmware executing on a programmable processor, or any combination of two or more of hardware, software, and firmware. The methods provided are implemented in any of a variety of devices, such as a general purpose computer, a processor, or a processor core. Suitable processors include, by way of example, a general purpose processor, a special purpose processor, a conventional processor, a digital signal processor (DSP), a graphics processing unit (GPU), a parallel accelerated processor, a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), and/or a state machine.

In one or more implementations, the methods and procedures provided herein are implemented in a computer program, software, or firmware incorporated in a non-transitory computer-readable storage medium for execution by a general purpose computer or a processor. Examples of non-transitory computer-readable storage mediums include a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

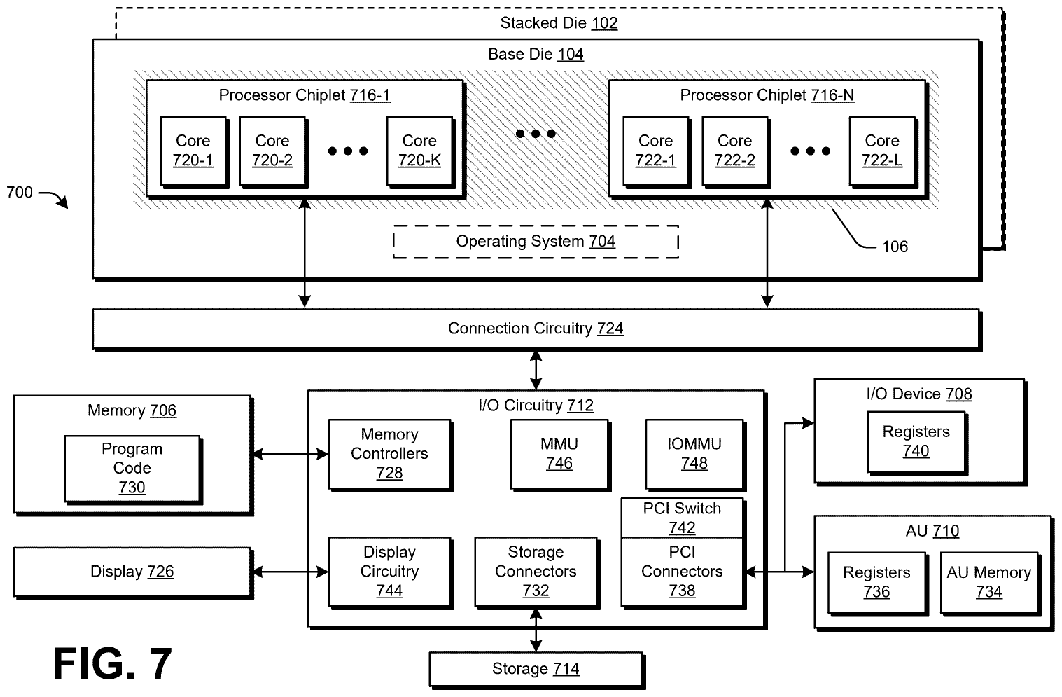

FIG. 7 is a block diagram of a processing system configured to execute one or more applications, in accordance with one or more implementations.

FIG. 7 includes a processing system 700 configured to execute one or more applications, such as compute applications (e.g., machine-learning applications, neural network applications, high-performance computing applications, databasing applications, gaming applications), graphics applications, and the like. Examples of devices in which the processing system is implemented include, but are not limited to, a server computer, a personal computer (e.g., a desktop or tower computer), a smartphone or other wireless phone, a tablet or phablet computer, a notebook computer, a laptop computer, a wearable device (e.g., a smartwatch, an augmented reality headset or device, a virtual reality headset or device), an entertainment device (e.g., a gaming console, a portable gaming device, a streaming media player, a digital video recorder, a music or other audio playback device, a television, a set-top box), an Internet of Things (IoT) device, an automotive computer or computer for another type of vehicle, a networking device, a medical device or system, and other computing devices or systems.

In the illustrated example, the processing system 700 includes a central processing unit (CPU), which includes a base die 104, and optionally, a stacked die 102, as described with reference to FIGS. 1 through 6. In one or more implementations, the CPU is configured to run an operating system (OS) 704 that manages the execution of applications. For example, the OS 704 is configured to schedule the execution of tasks (e.g., instructions) for applications, allocate portions of resources (e.g., system memory 706, CPU, input/output (I/O) device 708, accelerator unit (AU) 710, storage 714) for the execution of tasks for the applications, provide an interface to I/O devices (e.g., I/O device 708) for the applications, or any combination thereof.

In this example, the stacked die 102, the base die 104, and/or the communication channels 106 are in a CPU and/or in the memory 706. The communication channels 106 can be implemented by or a portion of data fabric. In variations, however, the stacked die 102, the base die 104, and/or the communication channels 106 are included in and/or are implemented by one or more different components of the processing system 700, such as a CPU, the memory 706, the I/O device 708, the AU 710, the I/O circuitry 712, the storage 714, and so forth. In at least one implementation, the stacked die 102, the base die 104, and/or the communication channels 106 or portions of the stacked die 102, the base die 104, and/or the communication channels 106 included in at least two of the depicted components of the processing system 700. By way of example, the stacked die 102, the base die 104, and/or the communication channels 106 may be included in or otherwise implemented by at least the CPU, the connection circuitry 724, data fabric, and the memory 706.

The base die 104 and/or the stacked die 102 includes one or more processor chiplets 716, which are communicatively coupled together by a communication channels 106 in one or more implementations.

Each of the processor chiplets 716, for example, includes one or more processor cores 720, 722 configured to concurrently execute one or more series of instructions, also referred to herein as “threads,” for an application. Further, the communication channels 106 communicatively couples each processor chiplet 716-N of the CPU, including the base die 104 and the stacked die 102, such that each processor core (e.g., processor cores 720) of a first processor chiplet (e.g., 716-1) is communicatively coupled to each processor core (e.g., processor cores 722) of one or more other processor chiplets 716. Though the example embodiment presented in FIG. 7 shows a first processor chiplet (716-1) having three processor cores (720-1, 720-2, 720-K) representing a K number of processor cores 722 and a second processor chiplet (716-N) having three processor cores (e.g., 722-1, 722-2, 722-L) representing an L number of processor cores 722, in other implementations (L being an integer number greater than or equal to one), each processor chiplet 716 may have any number of processor cores 720, 722. For example, each processor chiplet 716 can have the same number of processor cores 720, 722 as one or more other processor chiplets 716, a different number of processor cores 720, 722 as one or more other processor chiplets 716, or both.

Examples of connections which are usable to implement data fabric include but are not limited to, buses (e.g., a data bus, a system, an address bus), interconnects, memory channels, through silicon vias, traces, and planes. Other example connections include optical connections, fiber optic connections, and/or connections or links based on quantum entanglement.

Additionally, within the processing system 700, the base die 104 and/or the stacked die 102 are communicatively coupled to an I/O circuitry 712 by a connection circuitry 724. For example, each processor chiplet 716 is communicatively coupled to the I/O circuitry 712 by the connection circuitry 724. The connection circuitry 724 includes, for example, one or more data fabrics, buses, buffers, queues, and the like. The I/O circuitry 712 is configured to facilitate communications between two or more components of the processing system 700 such as between the base die 104 and the stacked die 102, system memory 706, display 726, universal serial bus (USB) devices, peripheral component interconnect (PCI) devices (e.g., I/O device 708, AU 710), storage 714, and the like.

As an example, system memory 706 includes any combination of one or more volatile memories and/or one or more non-volatile memories, examples of which include dynamic random-access memory (DRAM), static random-access memory (SRAM), non-volatile RAM, and the like. To manage access to the system memory 706 by the base die 104 and the stacked die 102, the I/O device 708, the AU 710, and/or any other components, the I/O circuitry 712 includes one or more memory controllers 728. These memory controllers 728, for example, include circuitry configured to manage and fulfill memory access requests issued from the base die 104 and/or the stacked die 102, the I/O device 708, the AU 710, or any combination thereof. Examples of such requests include read requests, write requests, fetch requests, pre-fetch requests, or any combination thereof. That is to say, these memory controllers 728 are configured to manage access to the data stored at one or more memory addresses within the system memory 706, such as by the base die 104, the stacked die 102, the I/O device 708, and/or the AU 710.

When an application is to be executed by processing system 700, the OS 704 running on the base die 104 and/or the stacked die 102 (e.g., a CPU) is configured to load at least a portion of program code 730 (e.g., an executable file) associated with the application from, for example, a storage 714 into system memory 706. This storage 714, for example, includes a non-volatile storage such as a flash memory, solid-state memory, hard disk, optical disc, or the like configured to store program code 730 for one or more applications.

To facilitate communication between the storage 714 and other components of processing system 700, the I/O circuitry 712 includes one or more storage connectors 732 (e.g., universal serial bus (USB) connectors, serial AT attachment (SATA) connectors, PCI Express (PCIe) connectors) configured to communicatively couple storage 714 to the I/O circuitry 712 such that I/O circuitry 712 is capable of routing signals to and from the storage 714 to one or more other components of the processing system 700.

In association with executing an application, in one or more scenarios, the base die 104 and the stacked die 102 are configured to issue one or more instructions (e.g., threads) to be executed for an application to the AU 710. The AU 710 is configured to execute these instructions by operating as one or more vector processors, coprocessors, graphics processing units (GPUs), general-purpose GPUs (GPGPUs), non-scalar processors, highly parallel processors, artificial intelligence (AI) processors (also known as neural processing units, or NPUs), inference engines, machine-learning processors, other multithreaded processing units, scalar processors, serial processors, programmable logic devices (e.g., field-programmable logic devices (FPGAs)), or any combination thereof.

In at least one example, the AU 710 includes one or more compute units that concurrently execute one or more threads of an application and store data resulting from the execution of these threads in AU memory 734. This AU memory 734, for example, includes any combination of one or more volatile memories and/or non-volatile memories, examples of which include caches, video RAM (VRAM), or the like. In one or more implementations, these compute units are also configured to execute these threads based on the data stored in one or more physical registers 736 of the AU 710.

To facilitate communication between the AU 710 and one or more other components of processing system 700, the I/O circuitry 712 includes or is otherwise connected to one or more connectors, such as PCI connectors 738 (e.g., PCIe connectors) each including circuitry configured to communicatively couple the AU 710 to the I/O circuitry such that the I/O circuitry 712 is capable of routing signals to and from the AU 710 to one or more other components of the processing system 700. Further, the PCIe connectors 738 are configured to communicatively couple the I/O device 708 to the I/O circuitry 712 such that the I/O circuitry 712 is capable of routing signals to and from the I/O device 708 to one or more other components of the processing system 700.

By way of example and not limitation, the I/O device 708 includes one or more keyboards, pointing devices, game controllers (e.g., gamepads, joysticks), audio input devices (e.g., microphones), touch pads, printers, speakers, headphones, optical mark readers, hard disk drives, flash drives, solid-state drives, and the like. Additionally, the I/O device 708 is configured to execute one or more operations, tasks, instructions, or any combination thereof based on one or more physical registers 740 of the I/O device 708. In one or more implementations, such physical registers 740 are configured to maintain data (e.g., operands, instructions, values, variables) indicating one or more operations, tasks, or instructions to be performed by the I/O device 708.

To manage communication between components of the processing system 700 (e.g., AU 710, I/O device 708) that are connected to PCI connectors 738, and one or more other components of the processing system 700, the I/O circuitry 712 includes PCI switch 742. The PCI switch 742, for example, includes circuitry configured to route packets to and from the components of the processing system 700 connected to the PCI connectors 738 as well as to the other components of the processing system 700. As an example, based on address data indicated in a packet received from a first component (e.g., a CPU), the PCI switch 742 routes the packet to a corresponding component (e.g., an AU 710) connected to the PCI connectors 738.

Based on the processing system 700 executing a graphics application, for instance, the base die 104, the stacked die 102, the AU 710, or any combination thereof are configured to execute one or more instructions (e.g., draw calls) such that a scene including one or more graphics objects is rendered. After rendering such a scene, the processing system 700 stores the scene in the storage 714, displays the scene on the display 726, or both. The display 726, for example, includes a cathode-ray tube (CRT) display, liquid crystal display (LCD), light emitting diode (LED) display, organic light emitting diode (OLED) display, or any combination thereof. To enable the processing system 700 to display a scene on the display 726, the I/O circuitry 712 includes display circuitry 744. The display circuitry 744, for example, includes high-definition multimedia interface (HDMI) connectors, DisplayPort connectors, digital visual interface (DVI) connectors, USB connectors, and the like, each including circuitry configured to communicatively couple the display 726 to the I/O circuitry 712. Additionally or alternatively, the display circuitry 744 includes circuitry configured to manage the display of one or more scenes on the display 726 such as display controllers, buffers, memory, or any combination thereof.

Further, the base die 104, the stacked die 102, the AU 710, or any combination thereof are configured to concurrently run one or more virtual machines (VMs), which are each configured to execute one or more corresponding applications. To manage communications between such VMs and the underlying resources of the processing system 700, such as any one or more components of processing system 700, including the base die 104, the stacked die 102, the I/O device 708, the AU 710, and the system memory 706, the I/O circuitry 712 includes memory management unit (MMU) 746 and input-output memory management unit (IOMMU) 748. The MMU 746 includes, for example, circuitry configured to manage memory requests, such as from the base die 104 and/or the stacked die 102 to the system memory 706. For example, the MMU 746 is configured to handle memory requests issued from the base die 104 and the stacked die 102 and associated with a VM running on the base die 104 and/or the stacked die 102 (e.g., a CPU). These memory requests, for example, request access to read, write, fetch, or pre-fetch data residing at one or more virtual addresses (e.g., guest virtual addresses) each indicating one or more portions (e.g., physical memory addresses) of the system memory 706. Based on receiving a memory request from the base die 104 or the stacked die 102, the MMU 746 is configured to translate the virtual address indicated in the memory request to a physical address in the system memory 706 and to fulfill the request. The IOMMU 748 includes, for example, circuitry configured to manage memory requests (memory-mapped I/O (MMIO) requests) from the base die 104 or the stacked die 102 to the I/O device 708, the AU 710, or both, and to manage memory requests (direct memory access (DMA) requests) from the I/O device 708 or the AU 710 to the system memory 706. For example, to access the registers 740 of the I/O device 708, the registers 736 of the AU 710, and/or the AU memory 734, the base die 104 or the stacked die 102 issues one or more MMIO requests. Such MMIO requests each request access to read, write, fetch, or pre-fetch data residing at one or more virtual addresses (e.g., guest virtual addresses) which each represent at least a portion of the registers 740 of the I/O device 708, the registers 736 of the AU 710, or the AU memory 734, respectively. As another example, to access the system memory 706 without using the base die 104 or the stacked die 102 (e.g., the CPU), the I/O device 708, the AU 710, or both are configured to issue one or more DMA requests. Such DMA requests each request access to read, write, fetch, or pre-fetch data residing at one or more virtual addresses (e.g., device virtual addresses) which each represent at least a portion of the system memory 706. Based on receiving an MMIO request or DMA request, the IOMMU 748 is configured to translate the virtual address indicated in the MMIO or DMA request to a physical address and fulfill the request.

In variations, the processing system 700 can include any combination of the components depicted and described. For example, in at least one variation, the processing system 700 does not include one or more of the components depicted and described in relation to FIG. 7. Additionally or alternatively, in at least one variation, the processing system 700 includes additional and/or different components from those depicted. The 700 is configurable in a variety of ways with different combinations of components in accordance with the described techniques.

What is claimed is:

1. A system comprising:
a first die having one or more communication channels for routing data to a destination across the first die;
a switch configured to communicably couple to a second die stacked on the first die; and
steering logic configured to route the data to the destination via the switch and over one or more communication channels of the second die based on detection of the second die.

2. The system of claim 1, wherein the system further comprises the second die, and wherein the steering logic is further configured to detect presence of the second die.

3. The system of claim 2, wherein the steering logic is further configured to route the data to the destination over the one or more communication channels of the second die and bypass the one or more communication channels of the first die based on detecting the presence of the second die.

4. The system of claim 1, wherein the steering logic is further configured to both route the data over the one or more communication channels of the second die to the destination and route additional data over the one or more communication channels of the first die to the destination.

5. The system of claim 4, wherein the steering logic is further configured to route the data over the one or more communication channels of the second die to the destination based on at least one of:
a threshold latency for routing the data;
a threshold latency for routing the additional data;
a threshold bandwidth of the one or more communication channels of the first die; or
a threshold bandwidth of the one or more communication channels of the second die.

6. The system of claim 4, wherein the steering logic is further configured to route the data over the one or more communication channels of the second die to the destination based on at least one of:
minimizing a latency of routing the data over the one or more communication channels of the second die;
minimizing a latency of routing the additional data over the one or more communication channels of the first die;
maximizing an amount of data routed over the one or more communication channels of the second die during an interval of time; or
maximizing an amount of data routed over the one or more communication channels of the second die during the interval of time.

7. The system of claim 4, wherein a transmission time period associated with the additional data is greater than a transmission time period associated with the data.

8. The system of claim 4, wherein the steering logic is configured to maximize an amount of data routed over the one or more communication channels of the second die and the one or more communication channels of the first die based on routing the data over the one or more communication channels of the second die and routing the additional data over the one or more communication channels of the first die.

9. The system of claim 4, wherein the steering logic is configured to minimize one or more of a transmission time period associated with the data or a transmission time period associated with the additional data based on routing the data over the one or more communication channels of the second die and routing the additional data over the one or more communication channels of the first die.

10. The system of claim 1, wherein the system further comprises the second die stacked on the first die, and wherein to route the data to the destination, the steering logic is further configured to route the data to the destination over the one or more communication channels of the first die to the destination based on one or more of a transmission time period associated with the data or a threshold corresponding to an amount of data routed over the one or more communication channels of the first die.

11. The system of claim 1, wherein to route the data to the destination, the steering logic is further configured to route the data over the one or more communication channels of the first die to the destination based on failing to detect the second die.

12. The system of claim 1, wherein, to detect the second die, the steering logic is further configured to receive a signal associated with one or more of a fuse, configuration information, or a pad, wherein the signal indicates the second die is stacked on the first die.

13. A method comprising:
detecting a second die stacked on a first die, the first die having one or more communication channels for routing data to a destination across the first die; and
routing, via a switch on the first die configured to communicably couple to the second die, the data to the destination over one or more communication channels of the second die based on detection of the second die.

14. The method of claim 13, wherein routing the data to the destination further comprises bypassing the one or more communication channels of the first die based on the detection of the second die.

15. The method of claim 13, further comprising routing both the data over the one or more communication channels of the second die to the destination and routing additional data over the one or more communication channels of the first die to the destination based on the detection of the second die.

16. The method of claim 15, wherein routing the data over the one or more communication channels of the second die to the destination is based on at least one of:
a threshold latency for routing the data;
a threshold latency for routing the additional data;
a threshold bandwidth of the one or more communication channels of the first die; or
a threshold bandwidth of the one or more communication channels of the second die.

17. The method of claim 15, wherein routing the data over the one or more communication channels of the second die to the destination is based on at least one of:
minimizing a latency of routing the data over the one or more communication channels of the second die;
minimizing a latency of routing the additional data over the one or more communication channels of the first die;
maximizing an amount of data routed over the one or more communication channels of the second die during an interval of time; or
maximizing an amount of data routed over the one or more communication channels of the second die during the interval of time.

18. The method of claim 15, wherein detecting the second die further comprises receiving a signal associated with one or more of a fuse, configuration information, or a pad, the signal indicating the second die is stacked on the first die.

19. A method comprising:
detecting an absence of a second die stacked on a first die, the first die having one or more communication channels for routing data to a destination across the first die; and
routing, via a switch on the first die configured to communicably couple to the second die, the data to the destination across the first die over the one or more communication channels of the first die based on detecting the absence of the second die.

20. The method of claim 19, wherein detecting the absence of the second die further is based on a signal associated with one or more of a fuse, configuration information, or a pad, the signal indicating the second die is not stacked on the first die.
